(19) United States
(12) Patent Application Publication
(10) Pub. No.: US 2018/0375290 A1
(43) Pub. Date: Dec. 27, 2018

(54) SEMICONDUCTOR LASER

(71) Applicant: Renesas Electronics Corporation, Tokyo (JP)

(72) Inventor: Fumito MIYASAKA, Tokyo (JP)

(73) Assignee: Renesas Electronics Corporation, Tokyo (JP)

(21) Appl. No.: 15/966,649

(22) Filed: Apr. 30, 2018

(30) Foreign Application Priority Data
Jun. 21, 2017 (JP) 2017-121742

(51) Int. Cl. H01S 5/22; H01S 5/20; B82Y 20/00; H01L 29/15; H01S 5/227; H01S 5/343

(52) U.S. Cl. CPC H01S 5/2207; H01S 5/2009; H01S 5/34313; H01L 29/15; H01S 5/227; B82Y 20/00

(57) ABSTRACT

The semiconductor laser including a substrate, and a p-type electron overflow prevention layer between an active layer and a p-type cladding layer further includes a p-type strained layer (p-type Al_{z}In_{1-z}As layer, where z>x), having a large band gap, between the p-type electron overflow prevention layer (p-type AlₓIn₁₋ₓAs layer) and p-type cladding layer. The provision of the p-type strained layer (p-type Al_{z}In_{1-z}As layer) reduces the heights of heterojunction spikes on a valence band, thereby lowering a barrier over which holes are injected into the active layer, and resultantly reducing the resistance in the elements and reducing heat generation in the semiconductor laser. In addition, a conduction band barrier (ΔEc) is raised in the energy band, thereby effectively preventing electron overflow. Thus, the semiconductor laser characteristics are improved.

### CROSS REFERENCE TO RELATED APPLICATIONS

The disclosure of Japanese Patent Application No. 2017-121742 filed on Jun. 21, 2017 including the specification, drawings and abstract is incorporated herein by reference in its entirety.

### BACKGROUND

This invention relates to semiconductor lasers, and is preferably applicable to a semiconductor laser using, for example, a group III-V compound semiconductor.

For semiconductor lasers (semiconductor devices) designed to operate at a speed as high as 10 Gbps or higher in optical communications, AlGaInAs-based semiconductor materials have been used since their large conduction band offsets and strong electron confinement effect can prevent electrons from overflowing from the active layer even at high temperatures.

For example, Patent Literature 1 (Japanese Unexamined Patent Application Publication No. Hei 11(1999)-54837) discloses a semiconductor laser having an SCH layer between a multiple quantum well layer and a cladding (p-AlInAs) layer. Over the SCH layer a semiconductor layer of p-type InGaAsP is provided.

Patent Literature 2 (Japanese Unexamined Patent Application Publication No. 2009-105458) discloses a semiconductor laser having a p-type InGaAlAs-GRIN-SCH layer and a p-type InAlAs electron stopping layer between an InGaAlAs-MQW layer and a p-type InP cladding layer. Over the p-type InAlAs electron stopping layer, a diffraction grating layer made of p-type InGaAsP is provided.

Patent Literature 3 (Japanese Unexamined Patent Application Publication No. 2010-212664) discloses a semiconductor laser having an active layer waveguide including an n-type AlGaInAs optical guide layer, a strain-compensated multiple quantum well active layer, a p-type AlGaInAs optical guide layer, and a p-type AlInAs electron overflow prevention layer. Over the p-type AlInAs electron overflow prevention layer, a protective layer made of p-type InGaAsP is provided.

### SUMMARY

The inventors of the present invention have been engaged with research and development of semiconductor lasers using group III-V compound semiconductors as mentioned above, and have been making considerable effort to improve the performance thereof. In the course of the research and development, the inventors have found that the semiconductor lasers using group III-V compound semiconductors still have room for improvement in the structure. Especially to improve the operating characteristics of semiconductor lasers at high temperatures, the semiconductor lasers are desired to produce heat as low as possible so as to be able to properly operate, for example, without temperature adjustment.

Other problems and novel features of the present invention will become apparent from the following description in the specification and the accompanying drawings.

Typical embodiments disclosed in this application will be briefly described below.

The semiconductor laser in an embodiment disclosed in this application includes a substrate and an electron overflow prevention layer between an active layer and a cladding layer. In such a semiconductor laser, a strained layer is provided between the electron overflow prevention layer and the cladding layer. The strained layer has a band gap larger than that of the electron overflow prevention layer.

The semiconductor laser in an embodiment disclosed in this application includes a substrate and an electron overflow prevention layer between an active layer and a cladding layer. In such a semiconductor laser, a strained layer is provided between the electron overflow prevention layer and the cladding layer. The strained layer has a band gap larger than that of the electron overflow prevention layer. The strained layer and electron overflow prevention layer form a junction with type-I band alignment, while the strained layer and cladding layer form a junction with type-II band alignment.

The semiconductor laser according to the typical embodiments disclosed in this application can provide improved semiconductor laser characteristics.

### BRIEF DESCRIPTION OF THE DRAWINGS

FIG. 1 is a perspective cross-sectional view showing the configuration of a semiconductor laser according to the first embodiment.

FIG. 2 is a cross-sectional view showing the configuration of a mesa and layers above and below the mesa of the semiconductor laser according to the first embodiment.

FIGS. 3A and 3B are diagrams each showing a band structure of the semiconductor laser according to the first embodiment.

FIG. 4 is a perspective cross-sectional view showing a fabrication step of the semiconductor laser according to the first embodiment.

FIG. 5 is a perspective cross-sectional view showing a fabrication step, following the step shown in FIG. 4, of the semiconductor laser according to the first embodiment.

FIG. 6 is a perspective cross-sectional view showing a fabrication step, following the step shown in FIG. 5, of the semiconductor laser according to the first embodiment.

FIG. 7 is a perspective cross-sectional view showing a fabrication step, following the step shown in FIG. 6, of the semiconductor laser according to the first embodiment.

FIG. 8 is a perspective cross-sectional view showing a fabrication step, following the step shown in FIG. 7, of the semiconductor laser according to the first embodiment.

FIG. 9 is a perspective cross-sectional view showing a fabrication step, following the step shown in FIG. 8, of the semiconductor laser according to the first embodiment.

FIG. 10 is a perspective cross-sectional view showing a fabrication step, following the step shown in FIG. 9, of the semiconductor laser according to the first embodiment.

FIG. 11 is a cross-sectional view showing the configuration of a mesa and layers above and below the mesa of the semiconductor laser according to the first application example of the first embodiment.

FIGS. 12A and 12B are cross-sectional views each showing the configuration of a mesa and layers above and below the mesa of the semiconductor laser according to the second application example of the first embodiment.

FIG. 13 is a perspective cross-sectional view showing the configuration of a semiconductor laser according to the second embodiment.

FIG. 14 is a perspective cross-sectional view showing a fabrication step of the semiconductor laser according to the second embodiment.

FIG. 15 is a perspective cross-sectional view showing a fabrication step, following the step shown in FIG. 14, of the semiconductor laser according to the second embodiment.

FIG. 16 is a perspective cross-sectional view showing a fabrication step, following the step shown in FIG. 15, of the semiconductor laser according to the second embodiment.

FIG. 17 is a block diagram of an exemplary optical communications system using the semiconductor laser according to the third embodiment.

FIG. 18 is a cross-sectional view showing the configuration of a semiconductor laser according to the first comparative example.

FIGS. 19A and 19B are diagrams each showing a band structure of the semiconductor laser according to the first comparative example.

FIG. 20 is a cross-sectional view showing the configuration of a semiconductor laser according to the second comparative example.

FIGS. 21A and 21B are diagrams each showing a band structure of the semiconductor laser according to the second comparative example.

FIG. 22 is a cross-sectional view showing the configuration of a semiconductor laser according to the third comparative example.

FIGS. 23A and 23B are diagrams each showing a band structure of the semiconductor laser according to the third comparative example.

FIGS. 24A and 24B are diagrams of band structures of type-I band alignment and type-II band alignment.

### DETAILED DESCRIPTION

In the embodiments below, the description will be described into a plurality of sections or embodiments if necessary; however, these are not irrelevant to each other unless stated explicitly, and one is related to the modifications, the details, the supplementary explanation, or the like of part or all of the other. Also, in the embodiments below, the number of components (including pieces, numerals, amount, range, etc.) is not limited to the particular number unless explicitly stated or specifically being limited to the particular number in principle, and may be more than or less than the described number.

It is needless to say that, in the embodiments below, the structure elements (including the steps) are not necessarily essential unless explicitly stated or clearly considered necessary in principle. Similarly, in the embodiments below, the shape, the positional relation, and the like of the structure elements include the shape and the like that are substantially the same or similar to those unless explicitly stated or clearly considered inappropriate in principle. This similarly applies to the number (pieces, numerals, amount, range, etc.).

Hereinafter, embodiments of the present invention will be described in detail with reference to the accompanying drawings. Note that components having the same function are denoted by the same or related reference symbols throughout all drawings for describing the embodiments, and the repetitive description thereof will be omitted. Also, when a plurality of similar components (portions) exist, an individual or specific portion will be described by adding a symbol to a collective term in some cases. In addition, the description of the same or similar portions is not repeated in principle unless particularly required in the embodiments described below.

Further, in the drawings used in the following embodiments, hatching is omitted in some cases even in a cross-sectional view so as to make the drawing easy to see.

Moreover, the size of respective portions does not correspond to that of an actual device in a cross-sectional view, and a specific portion is shown in a relatively enlarged manner in some cases so as to make the drawing easy to see.

### First Embodiment

With reference to the drawings, a semiconductor laser according to the first embodiment will be described below in detail.

### Explanation of Structure

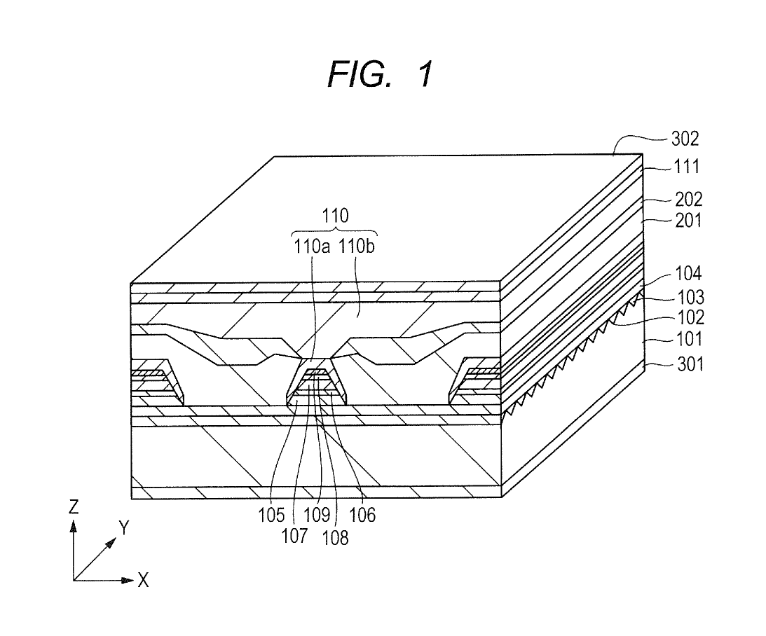

FIG. 1 is a perspective cross-sectional view showing the configuration of the semiconductor laser according to the first embodiment. As shown in FIG. 1, the semiconductor laser (semiconductor device) of the first embodiment includes a mesa that contains an active layer 106, and current block layers (201, 202) that bury both sides of the mesa. The mesa and current block layers are arranged over a substrate 101. The substrate 101 and a plurality of layers formed over the substrate 101 are group III-V compound semiconductors. The group III-V compound semiconductors contain group III elements and group V elements at a composition ratio of 1:1. The mesa functions as an optical waveguide. The current block layers (201, 202) block the current injected from an n-side electrode 301 and a p-side electrode 302, which will be described later, so as to direct the current only to the optical waveguide. With reference to FIG. 1, the semiconductor laser according to the first embodiment will be described below in further detail.

The semiconductor laser of this embodiment shown in FIG. 1 includes a substrate 101, a diffraction grating 102 formed in a surface of the substrate 101, an n-type guide layer 103, and an n-type buffer layer 104. These are arranged from the bottom in the order mentioned.

A mesa extends in Y direction substantially at a center of the n-type buffer layer 104. The mesa includes a layered structure in which an n-type optical guide layer 105, an active layer 106, a p-type optical guide layer 107, a p-type electron overflow prevention layer 108, and a p-type strained layer 109 are stacked in this order from the bottom, and a p-type first cladding layer (protective layer) 110a covering the top face and side faces of the layered structure.

The semiconductor laser of this embodiment further includes current block layers 201, 202 that bury the sides of the mesa. In addition, a p-type second cladding layer 110b and a p-type contact layer 111 are arranged in this order from the bottom over the mesa and current block layers 201, 202.

As described above, the semiconductor laser of this embodiment has a structure in which the active layer 106 is interposed between group III-V compound semiconductor layers of opposite conductivity arranged above and below the active layer 106.

A p-side electrode 302 is arranged over the uppermost p-type contact layer 111, while an n-side electrode 301 is arranged over the back face of the n-type substrate 101.

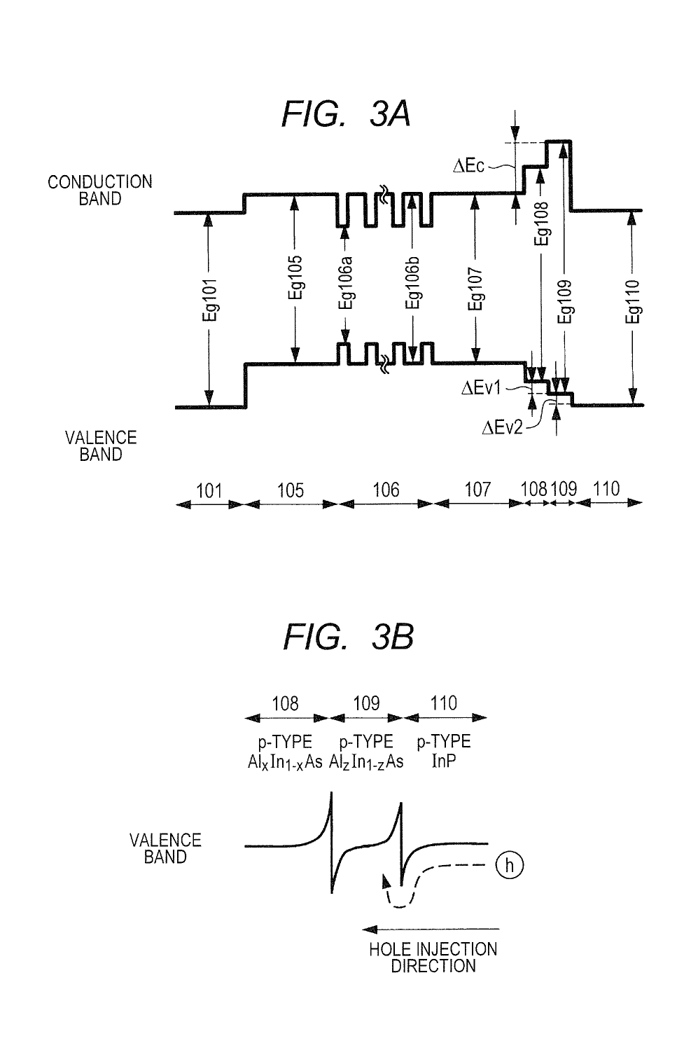

The substrate 101 is, for example, an n-type InP layer. This substrate 101 also functions as an n-type cladding layer. The substrate 101 has raised portions and recessed portions in a surface that serve as the diffraction grating 102. The n-type guide layer 103 is provided so as to fill up the recessed portions, which are part of the diffraction grating 102, in the surface of the substrate 101. The n-type guide layer 103 is, for example, an n-type InGaAsP layer. The n-type buffer layer 104 is, for example, an n-type InP layer. The n-type optical guide layer 105 is, for example, an n-type AlGaInAs layer. The active layer 106 includes, for example, a plurality of non-doped AlGaInAs layers. More specifically, the active layer 106 is a multiple quantum well structure composed of alternately stacked AlGaInAs well layers and AlGaInAs barrier layers, both of which contain group III elements with different compositions. The AlGaInAs well layers have a band gap smaller than that of the AlGaInAs barrier layers (see FIG. 3). The p-type optical guide layer 107 is, for example, a p-type AlGaInAs layer. The p-type electron overflow prevention layer 108 is, for example, a p-type AlInAs layer. More specifically, the p-type electron overflow prevention layer 108 is a p-type AlₓIn₁₋ₓAs layer. Note that x is, for example, approximately 0.48. The p-type strained layer 109 is made of a material whose band gap is larger than that of the material of the p-type electron overflow prevention layer 108. An example material of the p-type strained layer 109 is a p-type Al_{z}In_{1-z}As layer having a band gap larger than that of the p-type AlₓIn₁₋ₓAs layer (z>x). As described above, the Al composition of the p-type strained layer (p-type Al_{z}In_{1-z}As layer) 109 is higher than that of the p-type electron overflow prevention layer (p-type AlₓIn₁₋ₓAs layer) 108 (z>x). This produces tensile strain in the p-type strained layer (p-type Al_{z}In_{1-z}As layer) 109. It is preferable to set the thickness and the amount of strain of the p-type strained layer (p-type Al_{z}In_{1-z}As layer) 109 to values so as not to exceed the critical thickness. The p-type first cladding layer 110a is, for example, a p-type InP layer. The current block layer 201 is, for example, a Fe-doped InP layer. The current block layer 202 is, for example, an n-type InP layer. The p-type second cladding layer 110b is, for example, a p-type InP layer. The p-type first cladding layer 110a and p-type second cladding layer 110b make up a p-type cladding layer 110. The p-type contact layer 111 is, for example, a p-type InGaAs layer. The p-side electrode 302 is a layered film of, for example, a titanium (Ti) film, a platinum (Pt) film formed thereon, and a gold (Au) film formed thereon, while the n-side electrode 301 is a layered film of, for example, a gold-germanium (AuGe) alloy film, and a gold-nickel (AuNi) alloy film formed thereon.

In this embodiment, the p-type strained layer 109 is provided between the p-type electron overflow prevention layer 108 and p-type cladding layer 110. The p-type strained layer 109 having a band gap larger than that of the p-type electron overflow prevention layer 108 reduces the heights of heterojunction spikes on the valence band, and therefore lowers the barrier over which holes are injected to the active layer.

In addition, the higher conduction band energy level of the p-type strained layer 109 than that of the p-type electron overflow prevention layer 108 raises the barrier of the conduction band, thereby effectively preventing electron overflow.

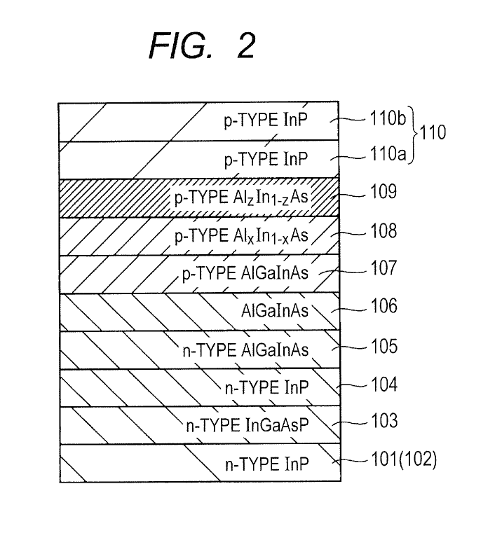

FIG. 2 is a cross-sectional view showing the configuration of a mesa and layers above and below the mesa of the semiconductor laser according to the first embodiment. Specifically, FIG. 2 illustrates how the layers, from the substrate (n-type InP layer) 101 to the p-type cladding layer (p-type InP layer) 110, are stacked. FIGS. 3A and 3B are diagrams each showing a band structure of the semiconductor laser according to the first embodiment. FIG. 3A illustrates the band structure of the substrate (n-type InP layer) 101, n-type optical guide layer (n-type AlGaInAs layer) 105, active layer (AlGaInAs well layers, AlGaInAs barrier layers) 106, p-type optical guide layer (p-type AlGaInAs layer) 107, p-type electron overflow prevention layer (p-type AlₓIn₁₋ₓAs layer) 108, p-type strained layer (p-type Al_{z}In_{1-z}As layer) 109, and p-type cladding layer (p-type InP layer) 110. The band structure of the diffraction grating 102, n-type guide layer (n-type InGaAsP layer) 103, and n-type buffer layer (n-type InP layer) 104 is omitted. Note that Eg denotes the band gap (band gap energy) of each layer. The band gap of each layer is a difference between the energy at the bottom edge of the conduction band and the energy at the top edge of the valence band.

FIG. 3B schematically illustrates the valence band structure of the p-type electron overflow prevention layer (p-type AlₓIn₁₋ₓAs layer) 108, p-type strained layer (p-type Al_{z}In_{1-z}As layer) 109, and p-type cladding layer (p-type InP layer) 110.

As illustrated in FIG. 3A, in this embodiment, the valence band discontinuity ΔEv in the range from the p-type electron overflow prevention layer 108 to the p-type cladding layer 110 is divided into ΔEv1 and ΔEv2 at the interfaces of the p-type electron overflow prevention layer (p-type AlₓIn₁₋ₓAs layer) 108, p-type strained layer (p-type Al_{z}In_{1-z}As layer) 109, and p-type cladding layer (p-type InP layer) 110. The band discontinuity ΔEv1 is the difference between the energy at the top edge of the valence band of the p-type electron overflow prevention layer (p-type AlₓIn₁₋ₓAs layer) 108 and the energy at the top edge of the valence band of the p-type strained layer (p-type Al_{z}In_{1-z}As layer) 109. The band discontinuity ΔEv2 is the difference between the energy at the top edge of the valence band of the p-type strained layer (p-type Al_{z}In_{1-z}As layer) 109 and the energy at the top edge of the valence band of the p-type cladding layer (p-type InP layer) 110.

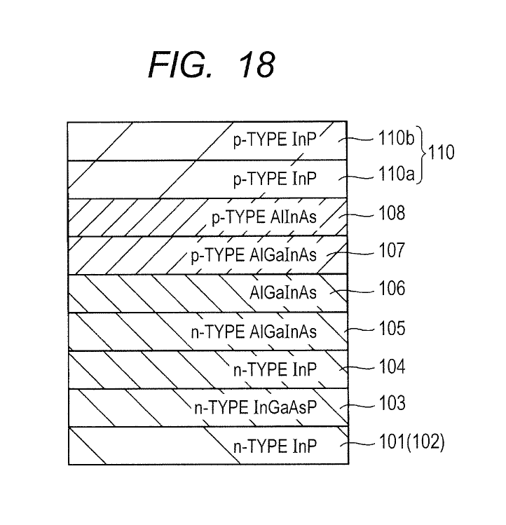

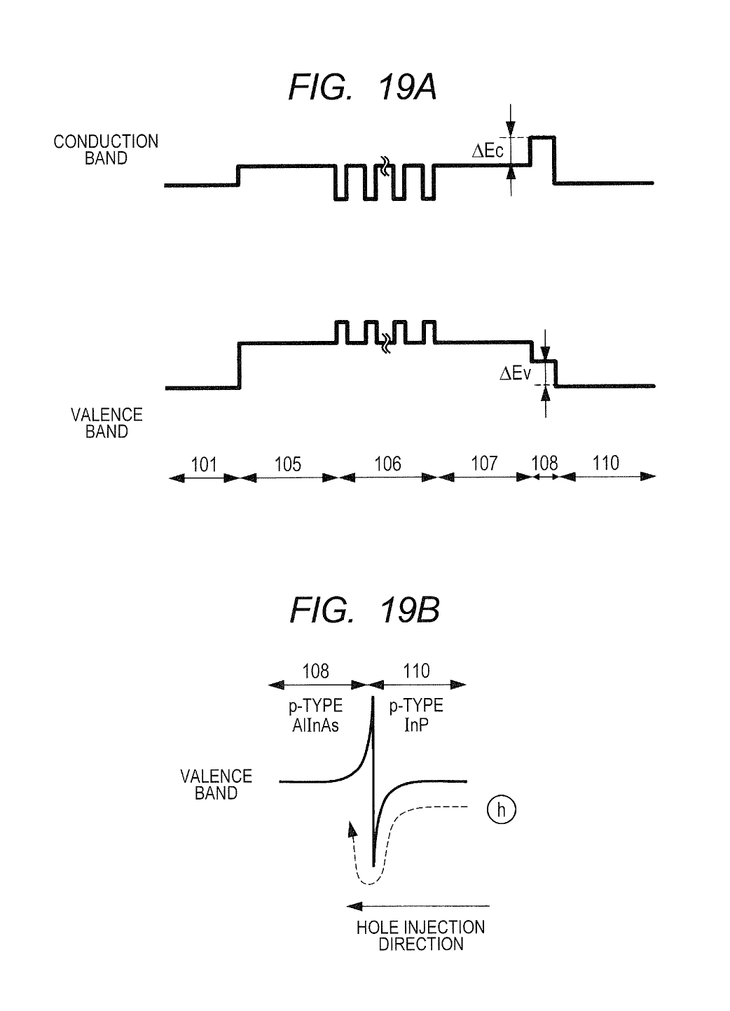

FIG. 18 is a cross-sectional view showing the configuration of a semiconductor laser according to the first comparative example. As shown in FIG. 18, the p-type strained layer (p-type Al_{z}In_{1-z}As layer) 109 is not provided in the first comparative example. FIGS. 19A and 19B are diagrams each showing a band structure of the semiconductor laser according to the first comparative example. FIG. 19A illustrates the band structure of a substrate (n-type InP layer) 101, an n-type optical guide layer (n-type AlGaInAs layer) 105, an active layer (AlGaInAs well layers, AlGaInAs barrier layers) 106, a p-type optical guide layer (p-type AlGaInAs layer) 107, a p-type electron overflow prevention layer (p-type AlₓIn₁₋ₓAs layer) 108, and a p-type cladding layer (p-type InP layer) 110. The band structure of a diffraction grating 102, an n-type guide layer (n-type InGaAsP layer) 103, and an n-type buffer layer (n-type InP layer) 104 is omitted. FIG. 19B schematically illustrates the valence band structure of the p-type electron overflow prevention layer (p-type AlₓIn₁₋ₓAs layer) 108, and p-type cladding layer (p-type InP layer) 110.

Since the first comparative example is not provided with the p-type strained layer (p-type Al_{z}In_{1-z}As layer) 109, the band discontinuity ΔEv is as large as 170 meV (FIG. 19A). On the contrary, this embodiment provides reduced heights of the heterojunction spikes on the valence band (see FIG. 3B and FIG. 19B). For example, when the amount of strain in the p-type strained layer (p-type Al_{z}In_{1-z}As layer) 109 is −0.5%, the band discontinuity is divided into approximately ΔEv1 of 45 meV and ΔEv2 of 125 meV. Alternatively, when the amount of strain in the p-type strained layer (p-type Al_{z}In_{1-z}As layer) 109 is −1.0%, the band discontinuity is divided into approximately ΔEv1 of 100 meV and ΔEv2 of 70 meV.

As described above, the provision of the p-type strained layer (p-type Al_{z}In_{1-z}As layer) 109 reduces the heights of the heterojunction spikes on the valence band, thereby lowering the barrier over which the holes are injected into the active layer, and resultantly reducing the resistance in the elements and reducing heat generation in the semiconductor laser. In addition, adjustment of the strain amount (Al composition z) can control the ratio between ΔEv1 and ΔEv2.

Furthermore, the higher conduction band energy level of the p-type strained layer (p-type Al_{z}In_{1-z}As layer) 109 than that of the p-type electron overflow prevention layer (p-type AlₓIn₁₋ₓAs layer) 108 further expands the conduction band discontinuity ΔEc. The band discontinuity ΔEc is the difference between the energy at the bottom edge of the conduction band of the p-type optical guide layer (p-type AlGaInAs layer) 107 or the aforementioned AlGaInAs barrier layer and the energy at the bottom edge of the conduction band of the p-type strained layer (p-type Al_{z}In_{1-z}As layer) 109.

Since the first comparative example is not provided with the p-type strained layer (p-type Al_{z}In_{1-z}As layer) 109, the band discontinuity ΔEc is approximately 150 meV to 200 meV. On the contrary, the provision of the p-type strained layer (p-type Al_{z}In_{1-z}As layer) 109 in this embodiment can increase the band discontinuity ΔEc in the conduction band. For example, when the amount of strain in the p-type strained layer (p-type Al_{z}In_{1-z}As layer) 109 is −0.5%, ΔEc is approximately 250 meV to 300 meV. Alternatively, when the amount of strain in the p-type strained layer (p-type Al_{z}In_{1-z}As layer) 109 is −1.0%, ΔEc is approximately 350 meV to 400 meV.

As described above, the provision of the p-type strained layer (p-type Al_{z}In_{1-z}As layer) 109 can raise the barrier (ΔEc) on the conduction band, thereby effectively preventing electron overflow.

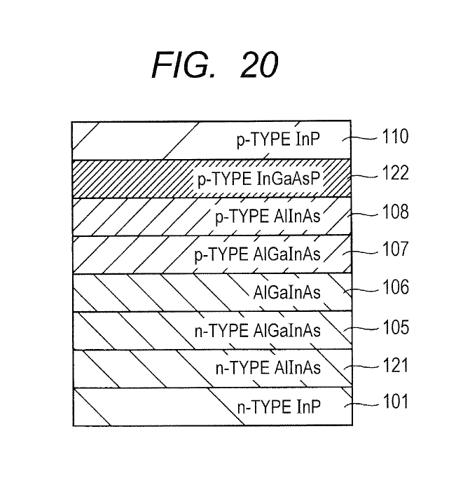

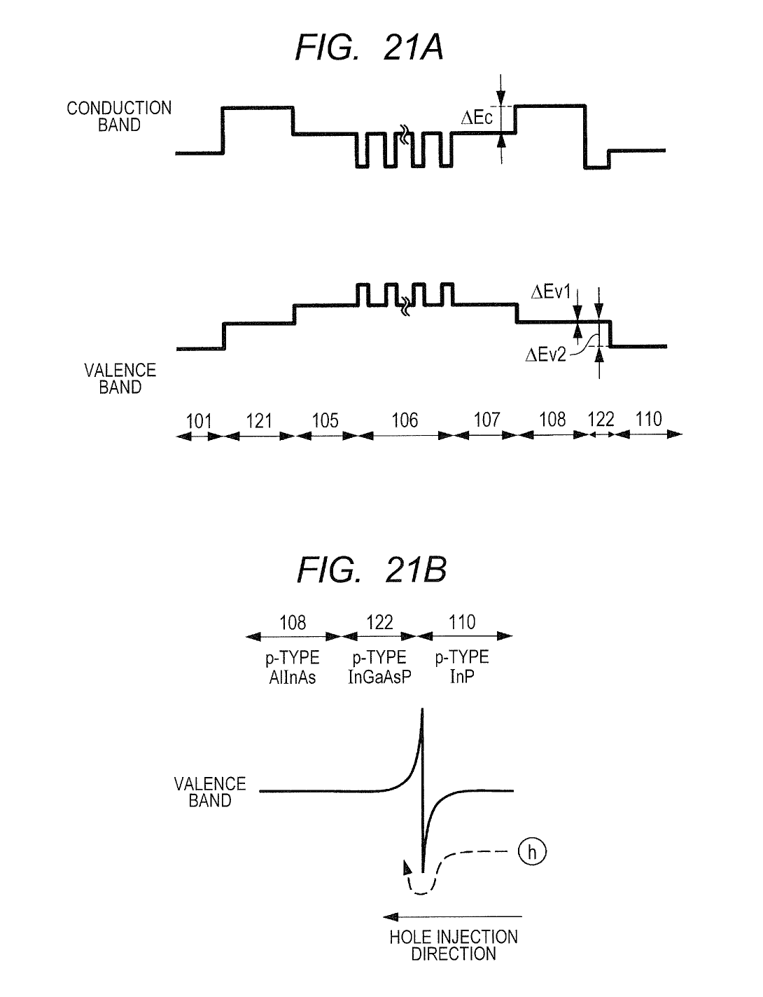

FIG. 20 is a cross-sectional view showing the configuration of a semiconductor laser according to the second comparative example. FIGS. 21A and 21B are diagrams each showing a band structure of the semiconductor laser according to the second comparative example. As shown in FIG. 20, in the second comparative example, a p-type InGaAsP layer 122 is provided between a p-type electron overflow prevention layer (p-type AlInAs layer) 108 and a p-type cladding layer (p-type InP layer) 110. The second comparative example also includes a cladding layer 121 made of an n-type AlInAs layer between a substrate 101 and an n-type optical guide layer 105.

In the second comparative example, the band gap of the layer (p-type InGaAsP layer) between the p-type electron overflow prevention layer (p-type AlInAs layer) 108 and the p-type cladding layer (p-type InP layer) 110 is smaller than that of the p-type electron overflow prevention layer 108 (see FIG. 21A). In this case, ΔEv1 is small, but ΔEv2 is large, and therefore a large heterojunction spike still remains (see FIG. 21B).

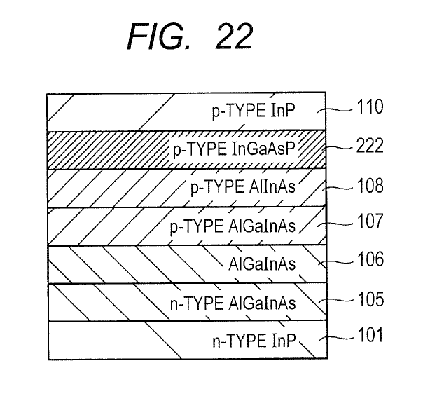

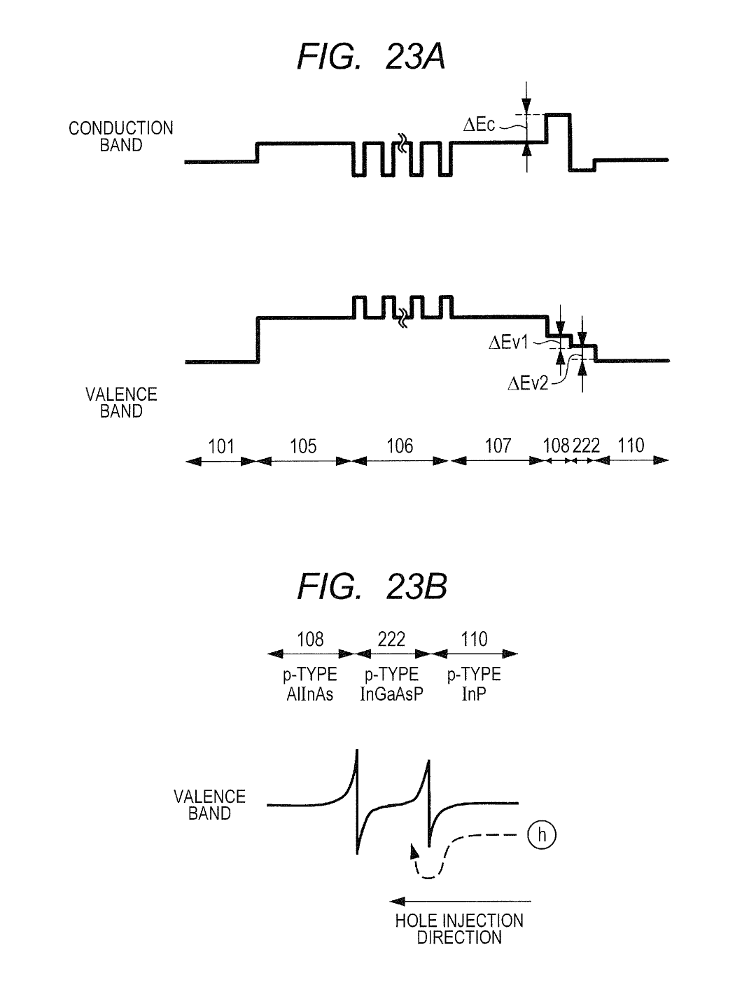

FIG. 22 is a cross-sectional view showing the configuration of a semiconductor laser according to the third comparative example. FIGS. 23A and 23B are diagrams each showing a band structure of the semiconductor laser according to the third comparative example. As shown in FIG. 22, in the third comparative example, a p-type InGaAsP layer 222 is provided between a p-type electron overflow prevention layer (p-type AlInAs layer) 108 and a p-type cladding layer (p-type InP layer) 110.

In the third comparative example, the band gap of the layer (p-type InGaAsP layer) between the p-type electron overflow prevention layer (p-type AlInAs layer) 108 and p-type cladding layer (p-type InP layer) 110 is smaller than that of the p-type electron overflow prevention layer 108 (FIG. 23A). In this case, ΔEv is divided into smaller band discontinuities ΔEv1 and ΔEv2, and therefore the heights of heterojunction spikes on the valence band are reduced. However, the small conduction band discontinuity ΔEc (FIG. 23A) may cause leakage of electrons in the conduction band from the active layer 106 to the p-type cladding layer 110, and therefore may hinder efficient recombination of holes and electrons in the active layer 106. On the contrary, the present embodiment can effectively reduce electron overflow as described above, and can efficiently recombine the holes and electrons in the active layer 106.

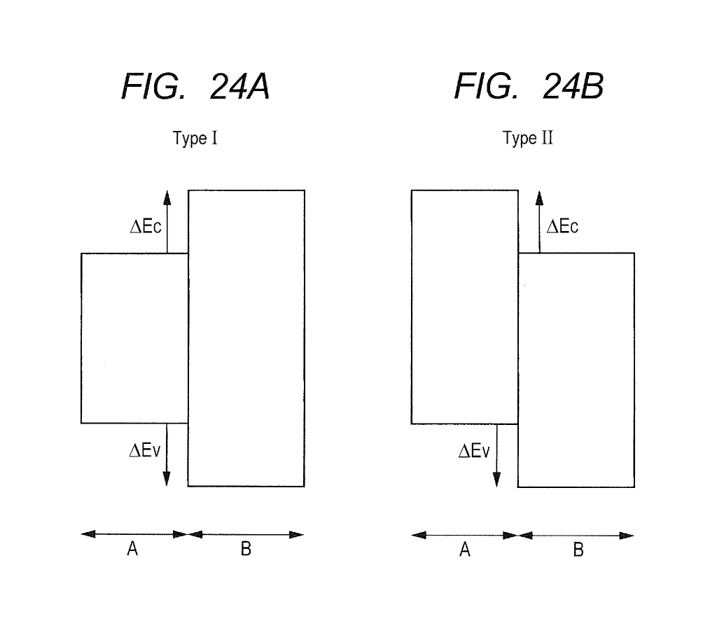

The comparison results between the second and third comparative examples and the first embodiment suggest that the p-type strained layer (p-type Al_{z}In_{1-z}As layer) 109 and p-type electron overflow prevention layer (p-type AlInAs layer) 108 preferably form a junction (heterojunction) with type-I band alignment. Also the comparison results suggest that the p-type strained layer (p-type Al_{z}In_{1-z}As layer) 109 and p-type cladding layer (p-type InP layer) 110 preferably form a junction (heterojunction) with type-II band alignment. FIGS. 24A and 24B are diagrams of band structures of type-I band alignment and type-II band alignment.

As shown in FIG. 24A, the type-I band alignment refers to a junction between a first layer A and a second layer B when the band gap energy of the second layer B is larger than the band gap energy of the first layer A, the energy at the bottom edge of the conduction band of the first layer A is lower than the energy at the bottom edge of the conduction band of the second layer B, and the energy at the top edge of the valence band of the first layer A is higher than the energy at the top edge of the valence band of the second layer B.

As shown in FIG. 24B, the type-II band alignment refers to a junction between a first layer A and a second layer B when the energy at the bottom edge of the conduction band of the first layer A is higher than the energy at the bottom edge of the conduction band of the second layer B, the energy at the top edge of the valence band of the first layer A is higher than the energy at the top edge of the valence band of the second layer B, and the energy at the bottom edge of the conduction band of the second layer B is higher than the energy at the top edge of the valence band of the first layer A.

As described above in detail, the p-type strained layer 109 provided between the p-type electron overflow prevention layer 108 and p-type cladding layer 110 in the first embodiment has a band gap larger than that of the p-type electron overflow prevention layer 108, and therefore the energy at the top edge of the valence band of the p-type strained layer 109 is positioned between the energy at the top edge of the valence band of the p-type electron overflow prevention layer 108 and the energy at the top edge of the valence band of the p-type cladding layer 110. Thus the provision of the p-type strained layer 109 can reduce the band discontinuity ΔEv stepwise, thereby lowering the heterojunction spikes on the valence band at the interface across the three layers. Lowering the heterojunction spikes allows efficient injection of holes into the active layer 106, and therefore can prompt recombination of the holes and electrons in the active layer 106. This can improve the operating characteristics of the semiconductor laser. In addition, facilitating injection of the holes into the active layer 106 can reduce resistance in the elements. As a result, heat generation caused by the current injection can be reduced.

As for the energy at the bottom edge of the conduction band, since the energy at the bottom edge of the conduction band of the p-type strained layer 109 can be raised higher than the energy at the bottom edge of the conduction band of the p-type electron overflow prevention layer 108, the band discontinuity ΔEc on the conduction band can be increased, and therefore can efficiently prevent electron overflow. Even if high temperatures raise the electron energy, the p-type strained layer 109 blocks the electrons, thereby enabling efficient injection of the electrons into the active layer 106 and recombination of the electrons and holes in the active layer 106. This can improve the operating characteristics of the semiconductor laser.

As described above, the semiconductor laser of the first embodiment having both the aforementioned effects in the valence band and conduction band can improve the operating characteristics, more specifically, it can reduce the operating current, and increase the maximum optical output and reliability, as well as improving the high-speed modulation operating characteristics at high temperatures.

Especially, semiconductor lasers having a short cavity length of 120 μm to 200 μm set for the purpose of achieving high-speed modulation operation as high as 25 Gb/s or higher tend to suffer from characteristic deterioration at high temperatures because of the high carrier density in the active layer 106; however, the p-type strained layer 109 as introduced to the first embodiment can provide excellent characteristics even at high temperatures.

### Explanation of Fabrication Method

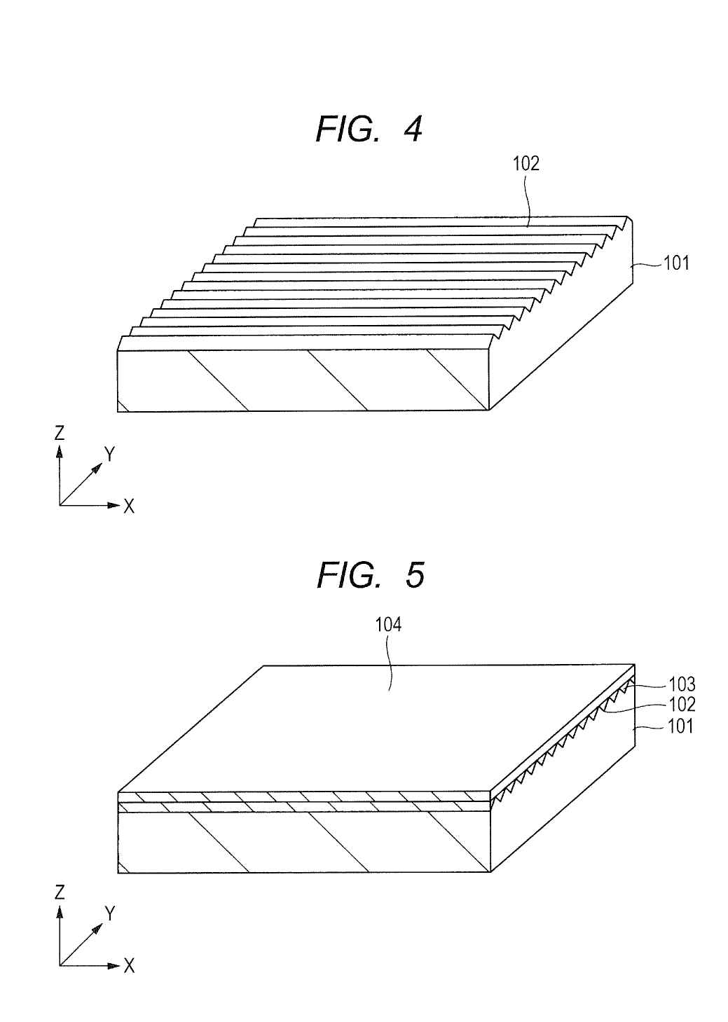

With reference to FIGS. 4 to 10, a fabrication method of the semiconductor laser according to the first embodiment will be described, while the configuration of the semiconductor laser will be more explicitly revealed. FIGS. 4 to 10 are perspective cross-sectional views showing fabrication steps of the semiconductor laser according to the first embodiment.

As shown in FIG. 4, for example, a substrate of indium phosphide (InP) doped with an n-type impurity is prepared as a substrate 101. The face (growth face) of this substrate is a (100) face.

Next, a diffraction grating 102 is formed in a surface of the substrate 101. A photoresist film with a stripe pattern (not shown) is formed over the substrate 101 by an electron beam exposure method, an interference exposure method, or other methods, and the surface of the substrate 101 is wet-etched using the photoresist film as a mask to obtain recessed portions. Subsequently, the photoresist film is removed. Through this step, the diffraction grating 102 with linear raised and recessed portions alternately arranged can be formed. The width of the recessed portions and the pitch (width of the raised portions) are, for example, approximately 200 nm.

Next, as shown in FIG. 5, an n-type guide layer 103 is formed so as to fill in the recessed portions of the diffraction grating 102, and an n-type buffer layer 104 is further formed over the n-type guide layer 103. The n-type guide layer 103 to be formed over the diffraction grating 102 is, for example, an n-type InGaAsP layer. For instance, a metal organic vapor phase epitaxy (MOVPE) reactor is used to grow the n-type guide layer (n-type InGaAsP layer) 103 through a crystallization process with a carrier gas and a source gas introduced in the reactor. Hydrogen gas is used as the carrier gas. Used for the source gas is a gas containing elements making up the III-V compound semiconductor layers. To form the n-type guide layer (n-type InGaAsP layer) 103, for example, trimethylindium (TMIn), triethylgallium (TEGa), AsH₃, and PH₃ are used as In, Ga, As, P materials, respectively, and disilane (Si₂H₆) is used as a material of the n-type impurity. The n-type guide layer (n-type InGaAsP layer) 103 has a thickness of, for example, approximately 30 nm, and is doped with an n-type impurity at a concentration (carrier density) of approximately 1×10¹⁸ cm⁻³. In addition, the composition wavelength of the n-type guide layer (n-type InGaAsP layer) 103, which corresponds to the band gap, is approximately 1130 nm to 1170 nm. Subsequently, an n-type InP layer, serving as the n-type buffer layer 104, is formed over the n-type guide layer (n-type InGaAsP layer) 103. The n-type InP layer is formed by, for example, stopping supplying the aforementioned triethylgallium (TEGa) and AsH₃. The n-type buffer layer (n-type InP layer) 104 has a thickness of, for example, approximately 30 nm, and is doped with an n-type impurity at a concentration (carrier density) of approximately 1×10¹⁸ cm⁻³.

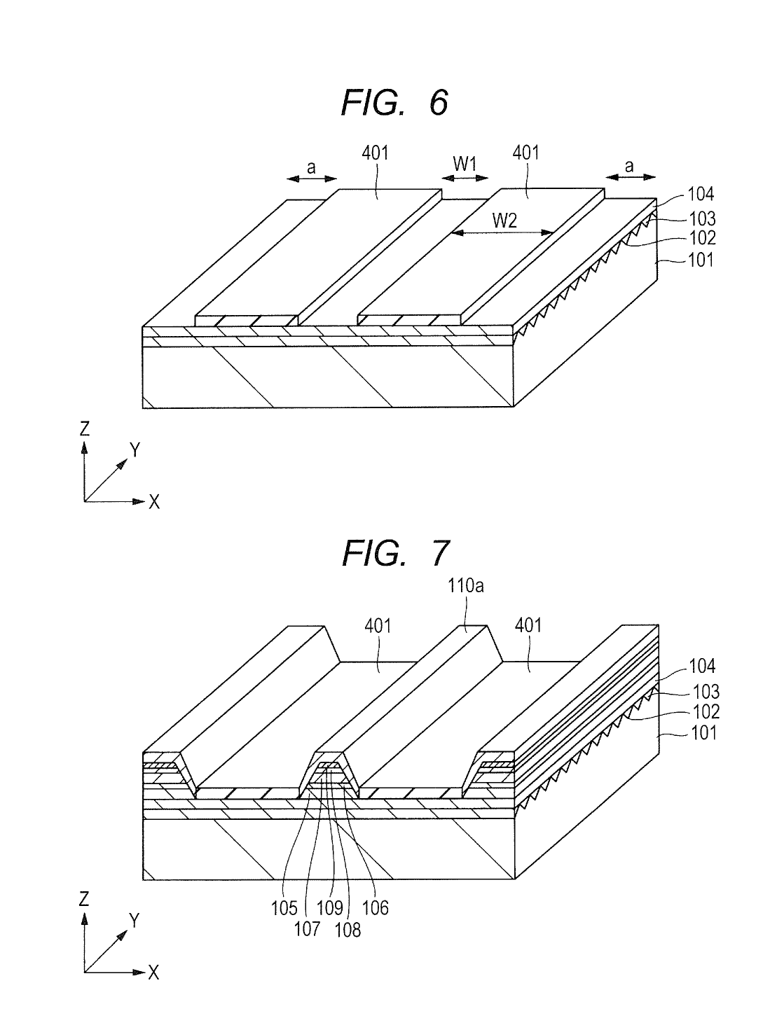

Next, as shown in FIG. 6, the substrate 101 is taken out from the MOVPE reactor, and a mask film 401 is selectively formed over the n-type buffer layer (n-type InP layer) 104. For example, an oxide silicon film is deposited as the mask film 401 over the n-type buffer layer (n-type InP layer) 104 by a thermal CVD method or other deposition methods. Subsequently, a photoresist film (not shown) is formed over the mask film (oxide silicon film) 401. The photoresist film has an opening in a region where a mesa is designed to be formed, and is used as a mask to etch the mask film (oxide silicon film) 401. Consequently, the mask film 401 is left only on the opposite sides of the regions where the mesa is to be formed, while the n-type buffer layer (n-type InP layer) 104 is exposed from the region where the mesa is to be formed. The region where the n-type buffer layer (n-type InP layer) 104 is exposed, or the region where the mesa is to be formed, is substantially rectangular in plan view, and has a width (W1) of, for example, approximately 1 to 2 μm. The remaining mask films 401 are also substantially rectangular in plan view, and each has a width (W2) of approximately 3 to 20 μm. The mask films 401 extend in direction [011]. At this stage, the n-type buffer layer (n-type InP layer) 104 is exposed on the outer sides of the mask films 401, and these outer parts of the n-type buffer layer (n-type InP layer) 104 are referred to as regions a.

Next, as shown in FIG. 7, a mesa is formed over the exposed part of the n-type buffer layer (n-type InP layer) 104 between the mask films 401.

Specifically, an n-type optical guide layer 105, an active layer 106, a p-type optical guide layer 107, a p-type electron overflow prevention layer 108, a p-type strained layer 109, and a p-type first cladding layer 110a are grown in sequence over the exposed n-type buffer layer (n-type InP layer) 104 between the mask films 401. In this growth step, the layers do not grow over the mask films 401, but over the exposed n-type buffer layer (n-type InP layer) 104 between the mask films 401 to form a mesa.

For example, the substrate 101 is placed in the MOVPE reactor, and an n-type AlGaInAs layer, serving as the n-type optical guide layer 105, is formed over the n-type buffer layer (n-type InP layer) 104. For example, a carrier gas and a source gas are introduced into the reactor to grow the n-type optical guide layer (n-type AlGaInAs layer) 105 through a crystallization process. Hydrogen gas is used as the carrier gas. Used for the source gas is a gas containing elements making up the III-V compound semiconductor layer, including trimethylaluminium (TMAl), triethylgallium (TEGa), trimethylindium (TMIn), and AsH₃, and disilane (Si₂H₆) is used as a material of the n-type impurity. The n-type optical guide layer (n-type AlGaInAs layer) 105 has a thickness of, for example, approximately 50 nm, and is doped with the n-type impurity at a concentration (carrier density) of approximately 1×10¹⁷ cm⁻³.

Subsequently, a multiple quantum well structure, serving as the active layer 106, is grown through a crystallization process over the n-type optical guide layer (n-type AlGaInAs layer) 105. The multiple quantum well structure is composed of alternately stacked AlGaInAs well layers and AlGaInAs barrier layers with different compositions of group III elements. The active layer (AlGaInAs well layers and AlGaInAs barrier layers) 106 is formed with trimethylaluminium (TMAl), triethylgallium (TEGa), trimethylindium (TMIn), and AsH₃ as materials of Al, Ga, In, As, respectively, by changing the flow rate of the materials of the group III elements (Al, Ga, In). This technique can alternately stack the AlGaInAs well layers and AlGaInAs barrier layers containing group III elements with different compositions. The AlGaInAs well layers are non-doped layers each having a thickness of approximately 5 nm, while the AlGaInAs barrier layers are non-doped layers each having a thickness of approximately 10 nm. Since the AlGaInAs well layers have compressive strain, and the AlGaInAs barrier layers have tensile strain, the active layer 106 achieves a strain-compensated structure. The total thickness of the active layer 106 is, for example, approximately 100 to 200 nm.

Next, a p-type AlGaInAs layer, serving as the p-type optical guide layer 107, is formed over the active layer (AlGaInAs well layers and AlGaInAs barrier layers) 106. To form the p-type optical guide layer (p-type AlGaInAs layer) 107, trimethylaluminium (TMAl), triethylgallium (TEGa), trimethylindium (TMIn), and AsH₃ are used as Al, Ga, In, As materials, respectively, and diethyl zinc (DEZn) is used as the material of a p-type impurity. The p-type optical guide layer (p-type AlGaInAs layer) 107 has a thickness of, for example, approximately 50 nm, and is doped with the p-type impurity at a concentration (carrier density) of approximately 5×10¹⁷ cm⁻³.

Next, a p-type AlInAs layer, serving as the p-type electron overflow prevention layer 108, is formed over the p-type optical guide layer (p-type AlGaInAs layer) 107.

To form the p-type electron overflow prevention layer (p-type AlₓIn₁₋ₓAs layer) 108, trimethylaluminium (TMAl), trimethylindium (TMIn), and AsH₃ are used as Al, In, As materials, respectively, and diethyl zinc (DEZn) is used as the material of a p-type impurity. The p-type electron overflow prevention layer (p-type AlₓIn₁₋ₓAs layer) 108 has a thickness of, for example, approximately 20 nm, and is doped with the p-type impurity at a concentration (carrier density) of approximately 1×10¹⁸ cm⁻³.

Next, a p-type Al_{z}In_{1-z}As layer, serving as the p-type strained layer 109, is formed over the p-type electron overflow prevention layer (p-type AlₓIn₁₋ₓAs layer) 108. In this step, the flow rate of the source gas is adjusted so as to satisfy z>x, or more specifically, such that the Al composition of the p-type strained layer (p-type Al_{z}In_{1-z}As layer) 109 becomes higher than the Al composition of the p-type electron overflow prevention layer (p-type AlₓIn₁₋ₓAs layer) 108. For example, the flow rate of trimethylaluminium (TMAl), which is an Al material, is set higher to form the p-type strained layer (p-type Al_{z}In_{1-z}As layer) 109. The p-type strained layer (p-type Al_{z}In_{1-z}As layer) 109 has a thickness of, for example, approximately 20 nm, and is doped with a p-type impurity at a concentration (carrier density) of approximately 1×10¹⁸ cm⁻³. It is preferable to set the thickness and the amount of strain of the p-type strained layer (p-type Al_{z}In_{1-z}As layer) 109 to values so as not to exceed the critical thickness. For example, when the amount of strain is −0.5%, the preferable thickness is 50 nm or lower, while when the amount of strain is −1.0%, the preferable thickness is 20 nm or lower.

Through the aforementioned steps, a layered structure, in which the n-type optical guide layer 105, active layer 106, p-type optical guide layer 107, p-type electron overflow prevention layer 108, and p-type strained layer 109 are stacked in this order from the bottom, is formed over the n-type buffer layer (n-type InP layer) 104 exposed between the mask films 401.

Next, a p-type InP layer, serving as the p-type first cladding layer 110a, is formed so as to cover the top face and side faces of the layered structure. To form the p-type first cladding layer (p-type InP layer) 110a, for example, trimethylindium (TMIn) and PH₃ are used as source gas of In, P materials, respectively, and diethyl zinc (DEZn) is used as the material of a p-type impurity. The p-type first cladding layer (p-type InP layer) 110a has a thickness of, for example, approximately 50 to 200 nm, and is doped with the p-type impurity at a concentration (carrier density) of approximately 1×10¹⁸ cm⁻³.

Thus, these steps can form the mesa including the aforementioned layered structure (the n-type optical guide layer 105, active layer 106, p-type optical guide layer 107, p-type electron overflow prevention layer 108, and p-type strained layer 109) and the p-type first cladding layer (p-type InP) 110a covering the layered structure. As described above, the MOVPE method enables continuous formation of individual layers that make up the mesa by changing the source gas. In this embodiment, similar structures to the mesa are grown over the n-type buffer layer (n-type InP layer) 104 exposed on the outer sides of the mask film 401 (regions a in FIG. 6); however, these structures do not function as lasers (see opposite side edges in FIG. 7).

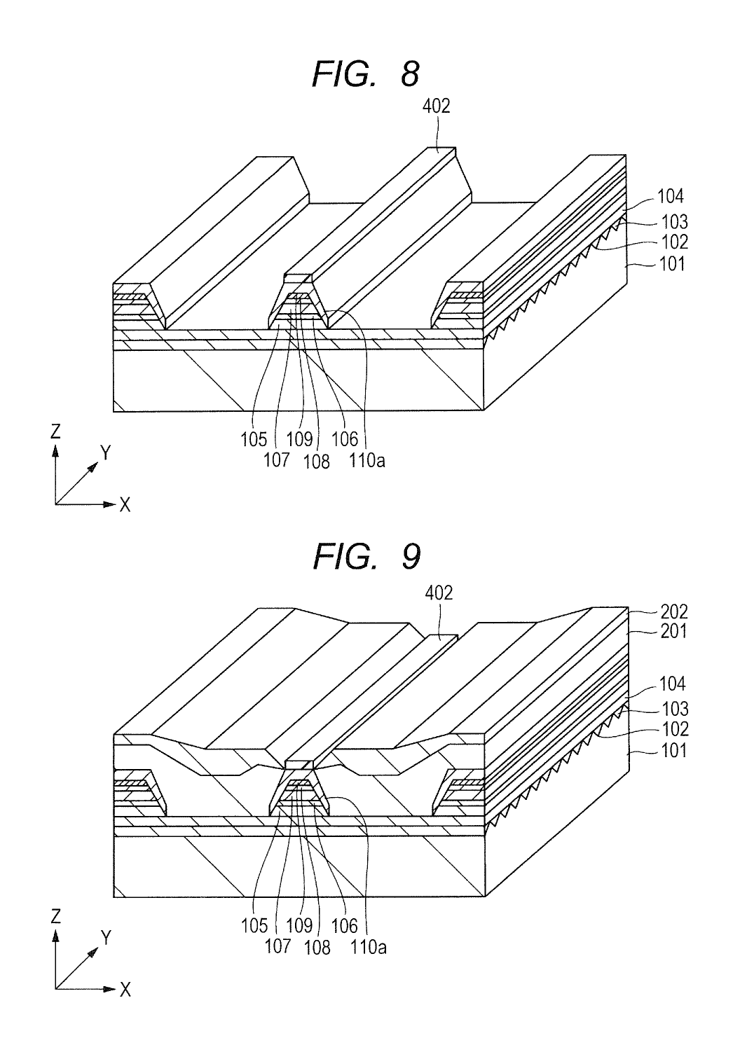

Next, as shown in FIG. 8, the mask films (oxide silicon films) 401 are removed by etching, and then a mask film 402 is formed over the top face of the mesa. For example, the substrate 101 is taken out from the MOVPE reactor and the mask films (oxide silicon films) 401 are removed by etching, and subsequently a mask film 402 is formed only over the top face of the mesa. More specifically, an oxide silicon film (not shown) is deposited over the entire surface by using a thermal CVD method or other deposition methods, and then a photoresist film (not shown) is formed over only the top face of the mesa. The photoresist film is used as a mask during removal of the oxide silicon film, and subsequently the photoresist film is removed to leave the mask film 402 composed of an oxide silicon film only over the top face of the mesa.

Next, as shown in FIG. 9, current block layers 201, 202 are formed so as to bury both sides of the mesa. For example, the substrate 101 is placed in the MOVPE reactor to form an InP layer doped with Fe (Fe-doped InP layer), serving as the current block layer 201, over all other regions than the mask film 402, or more specifically, over the side faces (p-type first cladding layer (p-type InP layer) 110a) of the mesa, and n-type buffer layer (n-type InP layer) 104. This layer has high resistance because the doped Fe traps electrons.

For example, a carrier gas and a source gas are introduced into the reactor to grow the current block layer (Fe-doped InP layer) 201 through a crystallization process. To form the current block layer (Fe-doped InP layer) 201, for example trimethylindium (TMIn) and PH₃ are used as source gas of In and P materials, respectively, and ferrocene (Cp₂Fe) is used to dope Fe. The current block layer (Fe-doped InP layer) 201 has a thickness of, for example, approximately 600 nm, and is doped with the impurity (Fe) at a concentration (electron trap density) of approximately 5×10¹⁷ cm⁻³.

Next, an n-type InP layer, serving as the current block layer 202, is formed over the current block layer (Fe-doped InP layer) 201.

To form the current block layer (n-type InP layer) 202, for example, trimethylindium (TMIn) and PH₃ are used as source gas of In and P materials, respectively, and disilane (Si₂H₆) is used as the material of an n-type impurity. The current block layer (n-type InP layer) 202 has a thickness of, for example, approximately 200 nm, and is doped with the n-type impurity at a concentration (carrier density) of approximately 1×10¹⁸ cm⁻³.

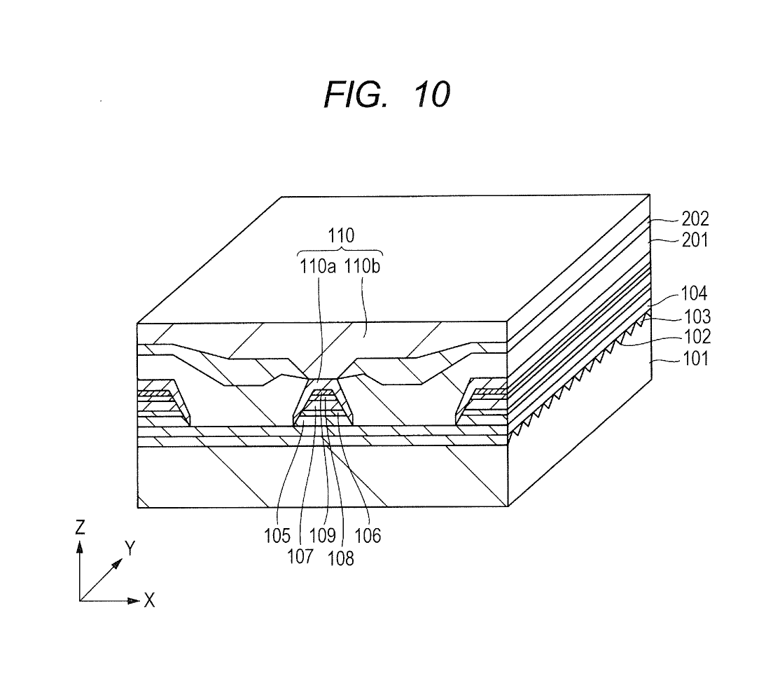

Next, as shown in FIG. 10, the mask film (oxide silicon film) 402 is removed by etching, and a p-type second cladding layer 110b is formed over the top face of the mesa and over the current block layer (n-type InP layer) 202. For example, the substrate 101 is taken out from the MOVPE reactor, and the mask film (oxide silicon film) 402 is removed by etching, and subsequently the substrate 101 is placed in the MOVPE reactor to form a p-type InP layer, serving as the p-type second cladding layer 110b, over the top face of the mesa and over the current block layer (n-type InP layer) 202. To form the p-type second cladding layer (p-type InP layer) 110b, for example, trimethylindium (TMIn) and PH₃ are used as source gas of In and P materials, respectively, and diethyl zinc (DEZn) is used as the material of a p-type impurity. The p-type second cladding layer (p-type InP layer) 110b has a thickness of, for example, approximately 1500 nm, and is doped with the p-type impurity at a concentration (carrier density) of approximately 1×10¹⁸ cm⁻³. Subsequently, a p-type InGaAs layer, serving as the p-type contact layer 111, is formed over the p-type second cladding layer (p-type InP layer) 110b.

To form the p-type contact layer (p-type InGaAs layer) 111, for example, trimethylindium (TMIn), triethylgallium (TEGa), and AsH₃ are used as source gas of In, Ga, As materials, respectively, and diethyl zinc (DEZn) is used as the material of a p-type impurity. The p-type contact layer (p-type InGaAs layer) 111 has a thickness of, for example, approximately 300 nm, and is doped with the p-type impurity at a concentration (carrier density) of approximately 1×10¹⁹ cm⁻³.

Then, a p-side electrode 302 is formed over the p-type contact layer (p-type InGaAs layer) 111. For example, a titanium (Ti) film, a platinum (Pt) film, and a gold (Au) film are formed in sequence over the p-type contact layer (p-type InGaAs layer) 111 by an evaporation method or other methods. Subsequently, the layered film (not shown) of the titanium (Ti) film, platinum (Pt) film, and gold (Au) film is patterned as needed, and subjected to heat treatment to make these metals into an alloy that makes ohmic contact with the semiconductor layers. Patterning refers to a process of making a film into a desirable shape by etching the film with a desirably-shaped film mask formed thereon.

Next, the substrate 101 is turned over to lie with the back face up, and the back face of the substrate 101 is ground to make the substrate 101 thinner. Then, for example, an alloy film of gold and germanium (AuGe) and an alloy film of gold and nickel (AuNi) are formed in sequence over the back face of the substrate 101 by an evaporation method or other methods. These metals are alloyed by heat treatment to form an n-side electrode 301 (see FIG. 1).

Then, the substrate 101 having a plurality of chip areas is cut into the chip areas. First, the substrate 101 is cleaved in between the chip areas. Specifically, the substrate 101 is cleaved along a scribe line between a chip area and an adjacent chip area. This cleavage process forms cleavage planes (planes extending in X direction). Next, an anti-reflection film is formed over one of the cleavage planes, and a high reflection film is formed over the other cleavage plane. The anti-reflection film used herein is, for example, a two-layered structure of titanium oxide (TiO₂)/alumina (Al₂O₃) having a reflectance of 0.1%. Each of the layers is formed by, for example, a sputtering method. The high reflection film used herein is, for example, a multilayer of alumina (Al₂O₃)/amorphous silicon (α-Si) having a reflectance of 75% or higher. Each of the layers is formed by, for example, a sputtering method. The substrate 101 is further cut along a side of the chip area in Y direction. Consequently, a chip piece is cut out. The cavity length of this semiconductor laser (distance between the cleavage planes, length of the mesa in Y direction) is 120 to 200 μm.

Through the above-described steps, the semiconductor laser according to the first embodiment can be formed.

### First Application Example

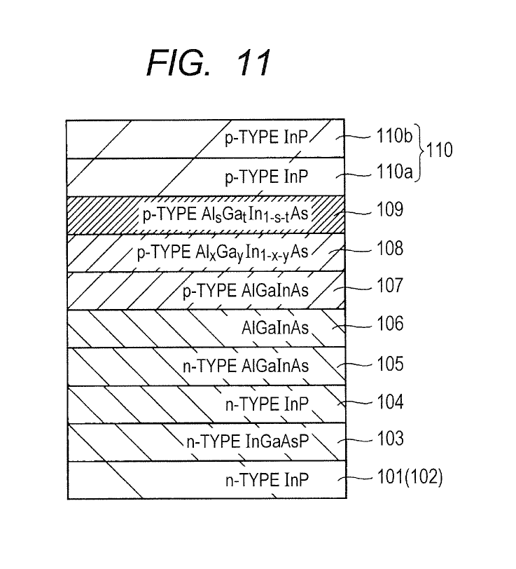

In the first embodiment (FIGS. 1 and 2), the p-type electron overflow prevention layer 108 and p-type strained layer 109 are p-type AlInAs layers, but may be AlGaInAs layers containing Ga. FIG. 11 is a cross-sectional view showing the configuration of a mesa and layers above and below the mesa of the semiconductor laser according to the first application example.

In this example, the p-type electron overflow prevention layer 108 is an AlGaInAs layer, and the p-type strained layer 109 is an AlGaInAs layer having a band gap larger than that of the material of the p-type electron overflow prevention layer 108. For example, a p-type AlₓGa_{y}In_{1-x-y}As layer is used as the p-type electron overflow prevention layer 108, while an AlₛGaₜIn₁₋ₛ₋ₜAs layer is used as the p-type strained layer 109. The band gap of the p-type strained layer 109 can be adjusted to be larger than that of the p-type electron overflow prevention layer 108 by setting the composition of Al plus Ga of the p-type strained layer 109 to be higher (s+t>x+y), or by setting the composition of In of the p-type strained layer 109 to be lower (1-s-t<1-x-y).

### Second Application Example

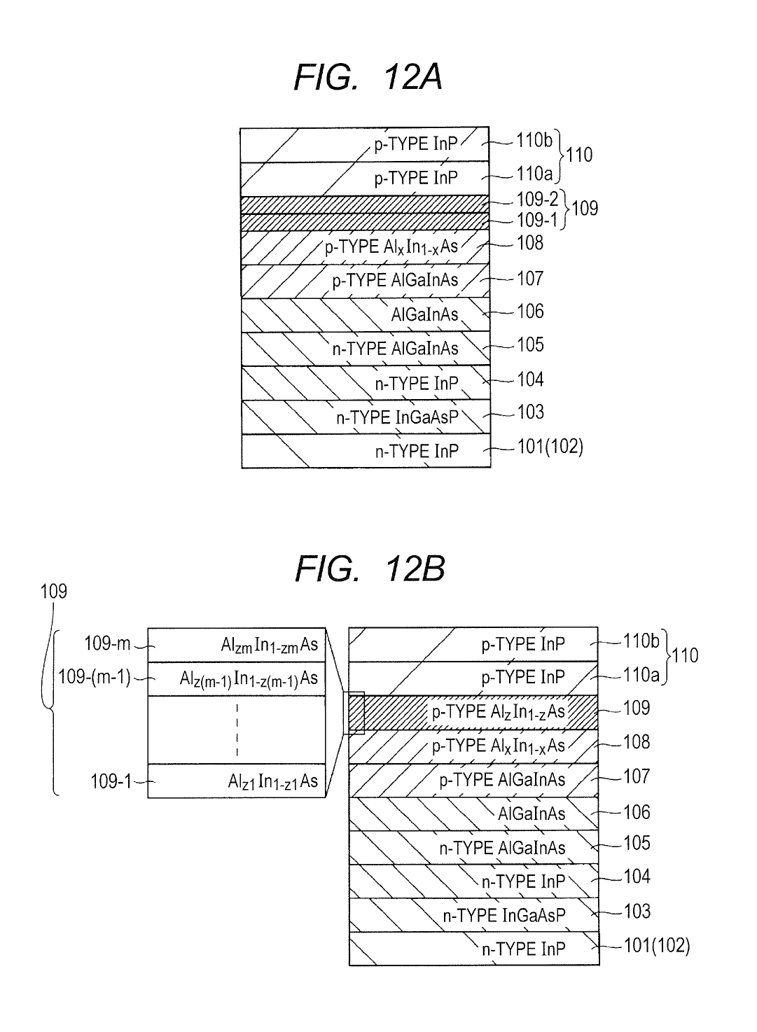

In the first embodiment (FIGS. 1 and 2), the p-type strained layer 109 is a monolayer, but maybe composed of multiple layers. FIGS. 12A and 12B are cross-sectional views each showing the configuration of a mesa and layers above and below the mesa of the semiconductor laser according to the second application example. FIG. 12A illustrates a p-type strained layer 109 composed of a two-layered film, while FIG. 12B illustrates a p-type strained layer 109 composed of an m-layered film.

As shown in FIG. 12A, the p-type strained layer 109 includes a first p-type strained layer 109-1 and a second p-type strained layer 109-2 arranged in this order from the side of the p-type electron overflow prevention layer 108. In this example, the first p-type strained layer 109-1 has a band gap larger than that of the p-type electron overflow prevention layer 108, and the second p-type strained layer 109-2 has a band gap larger than that of the first p-type strained layer 109-1. The first p-type strained layer 109-1 has an Al composition higher than that of the p-type electron overflow prevention layer 108, and the second p-type strained layer 109-2 has an Al composition higher than that of the first p-type strained layer 109-1.

As shown in FIG. 12B, the p-type strained layer 109 is an m-layered film including a first p-type strained layer 109-1, an (m-1)th p-type strained layer 109-(m-1), . . . , and an mth p-type strained layer 109-m (m is a positive integer). In this example, the first p-type strained layer 109-1 has a band gap larger than that of the p-type electron overflow prevention layer 108, and the mth p-type strained layer 109-m has a band gap larger than that of the (m-1)th p-type strained layer 109-(m-1). The first p-type strained layer 109-1 has an Al composition higher than that of the p-type electron overflow prevention layer 108, and the mth p-type strained layer 109-m has an Al composition higher than that of the (m-1)th p-type strained layer 109-(m-1). Specifically, where the p-type electron overflow prevention layer 108 is a p-type AlₓIn₁₋ₓAs layer, and the p-type strained layer 109 is a multilayer film including a p-type Al_{Z1}In_{1-Z1}As layer, . . . , a p-type Al_{Z(m-1)}In_{1-Z(m-1)}As layer, and a p-type Al_{Zm}In_{1-Zm}As layer stacked from the bottom, an inequality x<z1< . . . <z(m-1)<zm is satisfied.

### Second Embodiment

In this embodiment, a semiconductor laser having a p-type cladding layer with an elevated portion that makes up a ridge will be described. Like components are denoted by like numerals as of the first embodiment and will not be further explained.

### Explanation of Structure

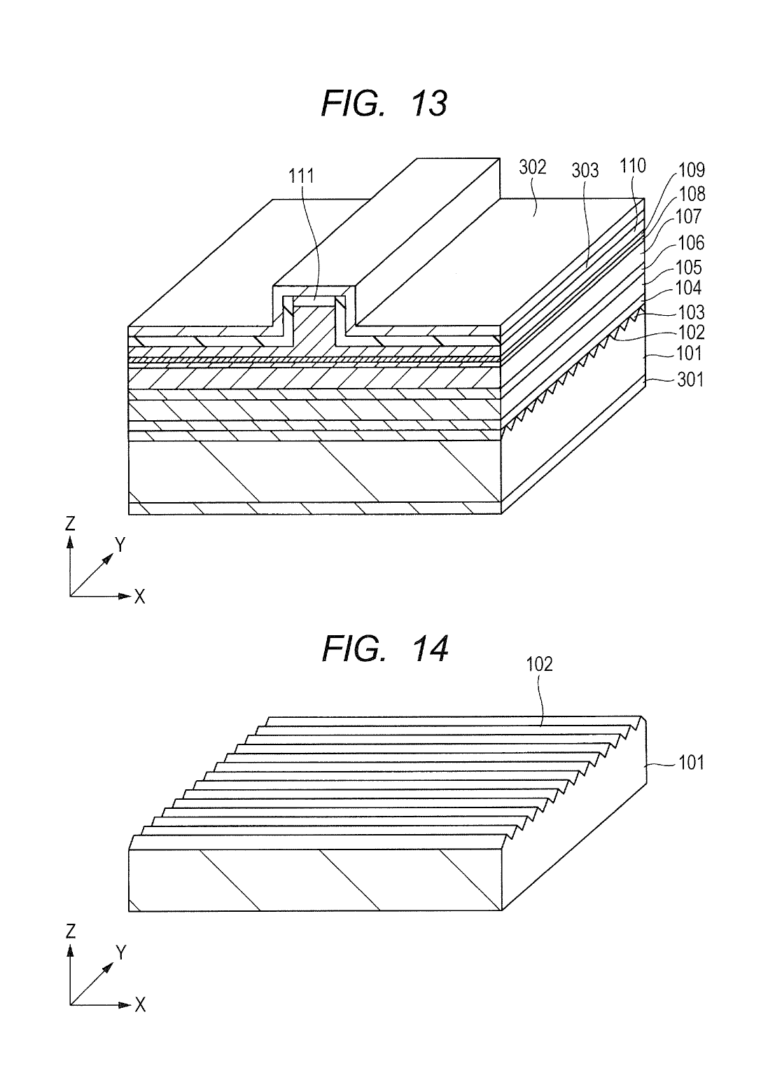

FIG. 13 is a perspective cross-sectional view showing the configuration of the semiconductor laser according to the second embodiment. As shown in FIG. 13, the semiconductor laser of the second embodiment includes a p-type cladding layer 110 that is patterned to have an elevated portion, and a p-type contact layer 111 provided over the elevated portion. The elevated portion of the p-type cladding layer 110 and the p-type contact layer 111 form a layered section (a ridge) that is in the shape of a stripe (line) in plan view and extends in Y direction.

Similar to the first embodiment, the semiconductor laser of the second embodiment uses a substrate 101, and has a plurality of group III-V compound semiconductor layers stacked in sequence over the substrate 101. Specifically, a diffraction grating 102, an n-type guide layer (n-type InGaAsP layer) 103, an n-type buffer layer (n-type InP layer) 104, and an n-type optical guide layer (n-type AlGaInAs layer) 105 are provided in sequence over the substrate (n-type InP layer) 101 in a similar manner to the first embodiment. Still over the n-type optical guide layer (n-type AlGaInAs layer) 105, an active layer (AlGaInAs well layers, AlGaInAs barrier layers) 106, a p-type optical guide layer (p-type AlGaInAs layer) 107, a p-type electron overflow prevention layer (p-type AlₓIn₁₋ₓAs layer) 108, and a p-type strained layer (p-type Al_{z}In_{1-z}As layer) 109 are provided in sequence. The p-type strained layer 109 is made of a material whose band gap is larger than that of the material of the p-type electron overflow prevention layer 108. For example, the p-type strained layer 109 is a p-type Al_{z}In_{1-z}As layer having a band gap larger than that of the p-type AlₓIn₁₋ₓAs layer (z>x). The Al composition of this p-type strained layer (p-type Al_{z}In_{1-z}As layer) 109 is higher than that of the p-type electron overflow prevention layer (p-type AlₓIn₁₋ₓAs layer) 108 (z>x). This produces tensile strain in the p-type strained layer (p-type Al_{z}In_{1-z}As layer) 109. It is preferable to set the thickness and the amount of strain of the p-type strained layer (p-type Al_{z}In_{1-z}As layer) 109 to values so as not to exceed the critical thickness.

Over the p-type strained layer (p-type Al_{z}In_{1-z}As layer) 109 provided is a p-type cladding layer (p-type InP layer) 110 that is processed to have an elevated portion. A p-type contact layer 111 is provided over the top face of the elevated portion of the p-type cladding layer (p-type InP layer) 110. The elevated portion of the p-type cladding layer (p-type InP layer) 110 and the p-type contact layer 111 form a layered section that is referred to as a ridge. The width of the ridge is, for example, approximately 1.0 to 2.0 μm. In addition, an insulating film (e.g., oxide silicon film) 303 is provided over side faces of the elevated portion and other areas (thin film part) of the p-type cladding layer (p-type InP layer) 110 except for the elevated portion. A p-side electrode 302 is provided over the p-type contact layer 111 and insulating film (e.g., oxide silicon film) 303, and an n-side electrode 301 is provided over the back face of the substrate 101.

In the semiconductor laser of the second embodiment, the active layer (AlGaInAs well layers, AlGaInAs barrier layers) 106 below the ridge plays a role as an optical waveguide, and the insulating film (e.g., oxide silicon film) 303 on the opposite sides of the ridge block current to direct the current to the ridge.

As described above, the semiconductor laser of the second embodiment also has the p-type strained layer 109 that is provided between the p-type electron overflow prevention layer 108 and p-type cladding layer 110 and has a band gap larger than that of the p-type electron overflow prevention layer 108 as with the first embodiment, thereby reducing the heights of heterojunction spikes on the valence band, and therefore lowering the barrier over which holes are injected into the active layer.

In addition, the higher conduction band energy level of the p-type strained layer 109 than that of the p-type electron overflow prevention layer 108 raises the barrier of the conduction band, thereby effectively preventing electron overflow.

### Explanation of Fabrication Method

With reference to FIGS. 14 to 16, a fabrication method of the semiconductor laser of the second embodiment will be described, while the configuration of the semiconductor laser will be more explicitly revealed. FIGS. 14 to 16 are perspective cross-sectional views showing fabrication steps of the semiconductor laser according to the second embodiment. Steps identical to those in the first embodiment will not be explained in detail.

As shown in FIG. 14, for example, a substrate of indium phosphide (InP) doped with an n-type impurity is prepared as a substrate 101, and a diffraction grating 102 is formed in the front surface of the substrate 101 in the same manner as the first embodiment. The width of the recessed portions and the pitch (width of the raised portions) of the diffraction grating 102 are, for example, approximately 200 nm.

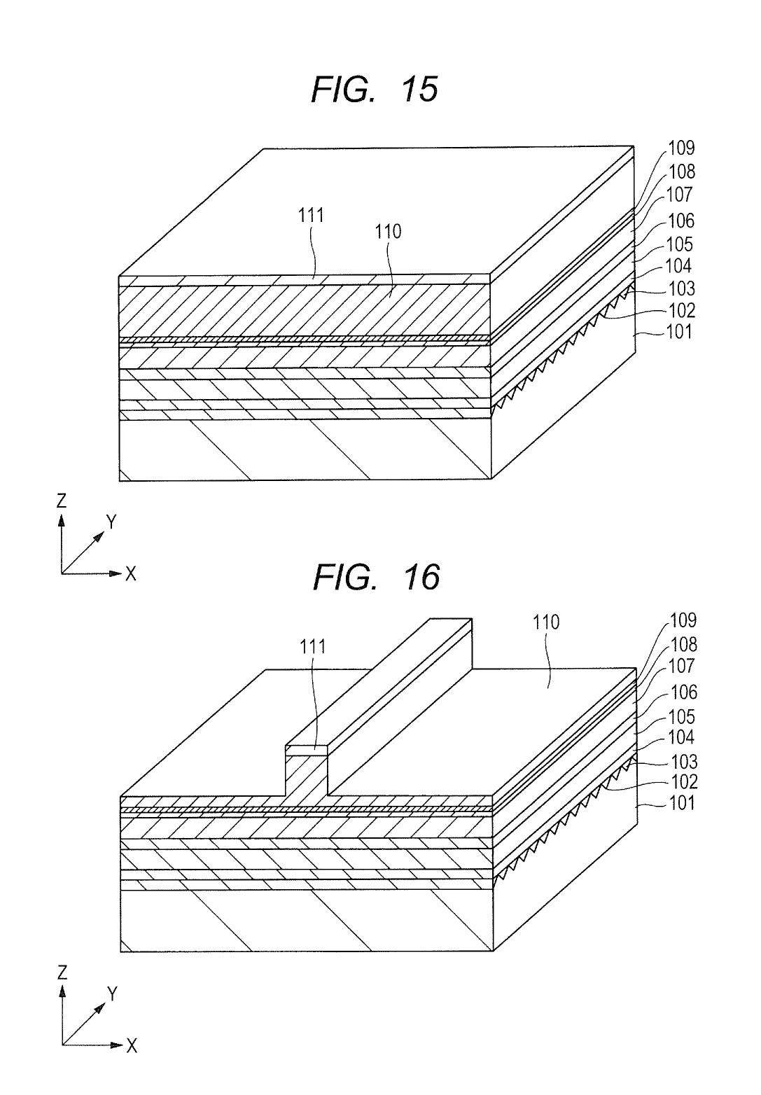

Next, as shown in FIG. 15, an n-type guide layer 103 is formed so as to fill in the recessed portions of the diffraction grating 102, and an n-type buffer layer 104 is further formed over the n-type guide layer 103. The n-type guide layer 103 and n-type buffer layer 104 can be formed in the same manner as the first embodiment.

Next, an n-type optical guide layer 105, an active layer 106, a p-type optical guide layer 107, a p-type electron overflow prevention layer 108, a p-type strained layer 109, a p-type cladding layer 110, and a p-type contact layer 111 are grown in sequence over the n-type buffer layer (n-type InP layer) 104. These layers can be formed by a MOVPE method using the same source gas as that used in the first embodiment. In addition, the thickness and impurity concentration of each layer can be set to the same as those in the first embodiment. However, since the p-type cladding layer 110 in the second embodiment is a monolayer, the thickness of the p-type cladding layer 110 is set to, for example, approximately 1500 nm. In the second embodiment, the aforementioned layers are formed in sequence over the entire face of the n-type buffer layer (n-type InP layer) 104 (FIG. 15).

Next, as shown in FIG. 16, the p-type cladding layer 110 and p-type contact layer 111 are patterned to form a ridge. For example, an oxide silicon film (not shown) is formed over the p-type contact layer 111 by a photolithographic method to cover a region where the ridge is designed to be formed, and then the p-type contact layer 111 and p-type cladding layer 110 are etched with the oxide silicon film used as a mask. The etching can be dry etching or wet etching. The p-type cladding layer 110 is etched so as to leave a lower part thereof. Leaving the thin p-type cladding layer (thin part) 110 over the surface of the p-type strained layer 109 can prevent oxidation of the Al-containing p-type strained layer 109.

Next, an insulating film 303 is formed only over the p-type cladding layer 110. Specifically, an oxide silicon film is deposited over the entire surface of the p-type cladding layer 110 by a thermal CVD method or other methods, and then a photoresist film (not shown) is formed over the oxide silicon film. Then, the photoresist film over the p-type contact layer 111, in other words, only over the ridge, is removed, and subsequently the oxide silicon film over the ridge is removed. These steps cover the side faces of the elevated portion and thin part of the p-type cladding layer 110 with the insulating film 303 of the oxide silicon film, but remove the insulating film 303 over the p-type contact layer 111, or over the ridge.

Next, a p-side electrode 302 is formed over the insulating film 303 and p-type contact layer 111. For example, a titanium (Ti) film, a platinum (Pt) film, and a gold (Au) film are formed in sequence over the p-type contact layer (p-type InGaAs layer) 111 by an evaporation method or other methods. Subsequently, the layered film (not shown) of the titanium (Ti) film, platinum (Pt) film, and gold (Au) film is patterned as needed, and subjected to heat treatment to make these metals into an alloy that makes ohmic contact with the semiconductor layers.

Next, the substrate 101 is thinned from the back face side, and an n-side electrode 301 is formed over the back face in the same manner as the first embodiment (see FIG. 13).

After that, as with the first embodiment, the substrate 101 having a plurality of chip areas is cut into the chip areas. First, the substrate 101 is cleaved in between the chip areas. Specifically, the substrate 101 is cleaved along a scribe line between a chip area and an adjacent chip area. This cleavage process forms cleavage planes (planes extending in X direction). Next, an anti-reflection film is formed over one of the cleavage planes, and a high reflection film is formed over the other cleavage plane. The anti-reflection film used herein is, for example, a two-layered structure of titanium oxide (TiO₂)/alumina (Al₂O₃) having a reflectance of 0.1%. Each of the layers is formed by, for example, a sputtering method. The high reflective layer used herein is, for example, a multilayer of alumina (Al₂O₃)/amorphous silicon (α-Si) having a reflectance of 75% or higher. Each of the layers is formed by, for example, a sputtering method. The substrate 101 is further cut along a side extending in Y direction of the chip area. Consequently, a chip piece is cut out. The cavity length of the semiconductor laser is, for example, 120 to 200 μm.

Through the above-described steps, the semiconductor laser according to the second embodiment can be formed.

The p-type electron overflow prevention layer 108 and p-type strained layer 109 in the semiconductor laser of the second embodiment can be AlGaInAs layers containing Ga as described in the first application example of the first embodiment.

Also in this case, the AlGaInAs layer used as the p-type strained layer 109 has a band gap larger than that of the AlGaInAs layer used as the p-type electron overflow prevention layer 108. For example, a p-type AlₓGa_{y}In_{1-x-y}As layer is used as the p-type electron overflow prevention layer 108, while an AlₛGaₜIn₁₋ₛ₋ₜAs layer is used as the p-type strained layer 109. In this case, the band gap of the p-type strained layer 109 can be adjusted to be larger than that of the p-type electron overflow prevention layer 108 by setting the composition of Al plus Ga of the p-type strained layer 109 to be higher (s+t>x+y), or by setting the composition of In of the p-type strained layer 109 to be lower (1-s-t<1-x-y).

The p-type strained layer 109 in the semiconductor laser of the second embodiment may be a multilayer film as described in the second application example of the first embodiment. Such a p-type strained layer 109 includes multiple layers stacked in the increasing order of the band gap from the bottom. For example, when the p-type electron overflow prevention layer 108 is a p-type AlₓIn₁₋ₓAs layer, and the p-type strained layer 109 is a multilayer film including a p-type Al_{Z1}In_{1-Z1}As layer, . . . , a p-type Al_{Z(m-1)}In_{1-z(m-1)}As layer, and a p-type Al_{Zm}In_{1-Zm}As layer, x<z1< . . . <z(m-1)<zm is satisfied.

### Third Embodiment

While there are no restrictions on applications of the semiconductor laser set forth in the first and second embodiments, the semiconductor laser can be used in optical communications systems.

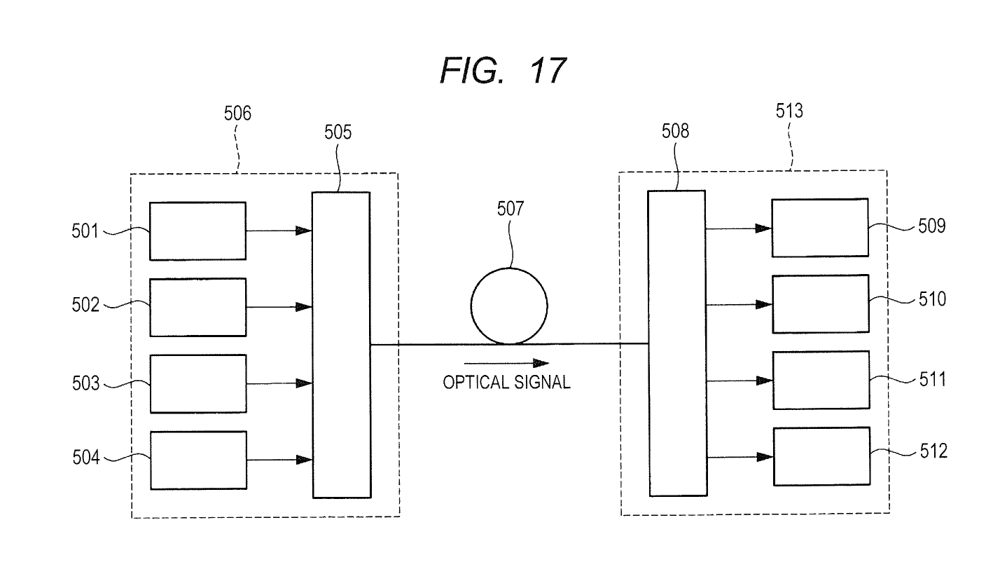

The optical communications system using the semiconductor laser is applicable to, for example, optical communications systems used for inter-datacenter communications. FIG. 17 is a block diagram of an exemplary optical communications system using the semiconductor lasers according to the third embodiment.

As shown in FIG. 17, the optical communications system of the third embodiment includes a transmitter 506, a receiver 513, and an optical fiber 507 coupling the transmitter 506 and receiver 513.

The transmitter 506 has a plurality of semiconductor lasers 501 to 504 each having a different emission wavelength. The semiconductor lasers 501 to 504 output optical signals, respectively, that in turn are combined at an optical multiplexer 505, and the combined optical signal is propagated to the optical fiber 507. This transmitter 506 may not be equipped with a temperature control mechanism, for example, typified by a Peltier element.

The receiver 513 has a plurality of light receiving elements 509 to 512 each having a different receive wavelength. The optical signal transmitted from the transmitter 506 and propagated through the optical fiber 507 is branched by an optical demultiplexer 508 by wavelength, and taken out as information by the respective light receiving elements 509 to 512.

The semiconductor lasers according to the first and second embodiments can be applied to the semiconductor lasers 501 to 504 of the optical communications system. The semiconductor lasers according to the first and second embodiments produce less heat, and have excellent characteristics at high temperatures. Therefore, even if the transmitter 506 has no temperature control mechanism, the semiconductor lasers can maintain their operating characteristics and can propagate optical signals with excellent characteristics. The absence of the temperature control mechanism can reduce the cost, and therefore can provide the optical communications system at lower prices. In addition, the system can be used in a high-temperature environment.

While the invention made by the present inventors has been described concretely with reference to the foregoing embodiments, it goes without saying that the present invention is not limited to the embodiments and that various modifications can be made without departing from the gist of the invention.

For example, the p-type strained layer 109 of an AlGaInAs layer described in the first application example may be formed with the multilayer structure as described in the second application example such that the p-type strained layer 109 includes multiple layers arranged from the bottom in the increasing order of the band gap.

### [Supplementary Note 1]

A semiconductor laser comprising:

a substrate;

a first semiconductor layer that is formed over the substrate and comprises a group III-V compound semiconductor;

a second semiconductor layer that is formed over the first semiconductor layer and comprises a group III-V compound semiconductor;

a third semiconductor layer that is formed between the first semiconductor layer and the second semiconductor layer, and comprises a group III-V compound semiconductor; and

a fourth semiconductor layer that is formed between the third semiconductor layer and the second semiconductor layer, and comprises a group III-V compound semiconductor,

wherein the first semiconductor layer has a refractive index higher than that of the second semiconductor layer, and

wherein the fourth semiconductor layer has a band gap larger than that of the third semiconductor layer.

### [Supplementary Note 2]

A semiconductor laser comprising:

a substrate;

a first semiconductor layer that is formed over the substrate and comprises a group III-V compound semiconductor;

a second semiconductor layer that is formed over the first semiconductor layer and comprises a group III-V compound semiconductor;

a third semiconductor layer that is formed between the first semiconductor layer and the second semiconductor layer, and comprises a group III-V compound semiconductor; and

a fourth semiconductor layer that is formed between the third semiconductor layer and the second semiconductor layer, and comprises a group III-V compound semiconductor,

wherein the first semiconductor layer has a refractive index higher than that of the second semiconductor layer,

wherein the fourth semiconductor layer has a band gap larger than that of the third semiconductor layer, and

wherein the fourth semiconductor layer and the third semiconductor layer form a junction with type-I band alignment.

### [Supplementary Note 3]

The semiconductor laser according to supplementary note 1 comprising:

an elevated portion that is formed over the substrate and is in the shape of a line in plan view; and

a fifth semiconductor layer that is formed both sides of the elevated portion, and comprises a group III-V compound semiconductor,

wherein the elevated portion comprises the first semiconductor layer, the second semiconductor layer, the third semiconductor layer, and the fourth semiconductor layer, and

wherein the fifth semiconductor layer has a resistance higher than that of the first semiconductor layer, the second semiconductor layer, the third semiconductor layer, and the fourth semiconductor layer.

### [Supplementary Note 4]

The semiconductor laser according to supplementary note 1 comprising:

an elevated portion that is formed over the substrate and is in the shape of a line in plan view; and

an insulating film that is formed both sides of the elevated portion, and

wherein the elevated portion comprises the second semiconductor layer.

What is claimed is:

1. A semiconductor laser comprising:
a substrate;
a first semiconductor layer that is formed over the substrate and comprises a group III-V compound semiconductor;
a second semiconductor layer that is formed over the first semiconductor layer and comprises a group III-V compound semiconductor;
a third semiconductor layer that is formed between the first semiconductor layer and the second semiconductor layer, and comprises a group III-V compound semiconductor; and
a fourth semiconductor layer that is formed between the third semiconductor layer and the second semiconductor layer, and comprises a group III-V compound semiconductor,
wherein the first semiconductor layer has a refractive index higher than that of the second semiconductor layer, and
wherein the fourth semiconductor layer has a band gap larger than that of the third semiconductor layer.

2. The semiconductor laser according to claim 1,
wherein the first semiconductor layer is a multiple quantum well structure including alternately stacked well layers and barrier layers, and
wherein the third semiconductor layer has a band gap larger than that of the barrier layers.

3. The semiconductor laser according to claim 2,
wherein energy at a top edge of a valence band of the fourth semiconductor layer is lower than energy at a top edge of a valence band of the third semiconductor layer.

4. The semiconductor laser according to claim 3,
wherein energy at a bottom edge of a conduction band of the fourth semiconductor layer is higher than energy at a bottom edge of a conduction band of the third semiconductor layer.

5. The semiconductor laser according to claim 4,
wherein energy at a bottom edge of a conduction band of the second semiconductor layer is lower than energy at a bottom edge of a conduction band of the fourth semiconductor layer, and
wherein energy at a top edge of a valence band of the second semiconductor layer is lower than energy at a top edge of a valence band of the fourth semiconductor layer.

6. The semiconductor laser according to claim 2,
wherein the third semiconductor layer comprises AlₓIn₁₋ₓAs,
wherein the fourth semiconductor layer comprises Al_{z}In_{1-z}As, and
wherein the Al composition ratio of the Al_{z}In_{1-z}As is higher than that of the and z>x is satisfied.

7. The semiconductor laser according to claim 6,
wherein the second semiconductor layer comprises InP.

8. The semiconductor laser according to claim 6,
wherein the fourth semiconductor layer has tensile strain.

9. The semiconductor laser according to claim 8,
wherein the fourth semiconductor layer includes a first layer, and a second layer over the first layer, and
wherein the Al composition ratio of the second layer is higher than that of the first layer.

10. The semiconductor laser according to claim 2,
wherein the third semiconductor layer and the fourth semiconductor layer comprise AlGaInAs.

11. The semiconductor laser according to claim 10,
wherein the third semiconductor layer comprises AlₓGa_{y}In_{1-x-y}As,
wherein the fourth semiconductor layer comprises AlₛGaₜIn₁₋ₛ₋ₜAs, and
wherein the In composition ratio of the AlₛGaₜIn₁₋ₛ₋ₜAs is higher than that of the AlₓGa_{y}In_{1-x-y}As, and 1-s-t<1-x-y is satisfied.

12. The semiconductor laser according to claim 11,
wherein the second semiconductor layer comprises InP.

13. The semiconductor laser according to claim 11,
wherein the fourth semiconductor layer has tensile strain.

14. The semiconductor laser according to claim 10,
wherein the fourth semiconductor layer includes a first layer, and a second layer over the first layer, and
wherein the second layer has a band gap larger than that of the first layer.

15. A semiconductor laser comprising:
a substrate;
a first semiconductor layer that is formed over the substrate and comprises a group III-V compound semiconductor;
a second semiconductor layer that is formed over the first semiconductor layer and comprises a group III-V compound semiconductor;
a third semiconductor layer that is formed between the first semiconductor layer and the second semiconductor layer, and comprises a group III-V compound semiconductor; and
a fourth semiconductor layer that is formed between the third semiconductor layer and the second semiconductor layer, and comprises a group III-V compound semiconductor,
wherein the first semiconductor layer has a refractive index higher than that of the second semiconductor layer,
wherein the fourth semiconductor layer has a band gap larger than that of the third semiconductor layer, and
wherein the fourth semiconductor layer and the third semiconductor layer form a junction with type-I band alignment.

16. The semiconductor laser according to claim 15,
wherein the fourth semiconductor layer and the second semiconductor layer form a junction with type-II band alignment.

17. The semiconductor laser according to claim 16,
wherein the third semiconductor layer comprises AlₓIn₁₋ₓAs,
wherein the fourth semiconductor layer comprises Al_{z}In_{1-z}As, and
wherein the Al composition ratio of the Al_{z}In_{1-z}As is higher than that of the AlₓIn₁₋ₓAs, and z>x is satisfied.

18. The semiconductor laser according to claim 17,
wherein the second semiconductor layer comprises InP.

19. The semiconductor laser according to claim 16,
wherein the third semiconductor layer and the fourth semiconductor layer comprise AlGaInAs.

20. The semiconductor laser according to claim 19,
wherein the third semiconductor layer comprises AlₓGa_{y}In_{1-x-y}As,
wherein the fourth semiconductor layer comprises AlₛGaₜIn₁₋ₛ₋ₜAs,
wherein the In composition ratio of the AlₛGaₜIn₁₋ₛ₋ₜAs is lower than that of the AlₓGa_{y}In_{1-x-y}As, and 1-s-t<1-x-y is satisfied, and
wherein the second semiconductor layer comprises InP.
